(19) United States
(12) Patent Application Publication
(10) Pub. No.: US 2012/0111390 A1
(43) Pub. Date: May 10, 2012

(54) HIGHLY CONCENTRATING SOLAR POWER GENERATION AND THERMAL COLLECTION APPARATUS

(76) Inventor: TUNG-YI DAI, Taipei County (TW)

(21) Appl. No.: 12/941,242

(22) Filed: Nov. 8, 2010

(51) Int. Cl. H01L 31/052; F24J 2/08

(52) U.S. Cl. 136/246; 126/698

(57) ABSTRACT

A highly concentrating solar power generation and thermal collection apparatus includes a multi-coated lens capable of reflecting UV light and visible light and allowing infrared light to transmit therethrough, a lens located at one side of the multi-coated lens for collecting and then concentrating sunlight on the multi-coated lens, a solar cell located on a light reflection path of the multi-coated lens for collecting the UV light and visible light reflected by the multi-coated lens, and a thermal collection unit located at a light transmission path of the multi-coated lens for collecting the infrared light transmitted through the multi-coated lens. The multi-coated lens can be differently designed to change its light reflecting and transmitting function while the locations for the solar cell and the thermal collection unit are exchanged accordingly. Therefore, the apparatus is able to generate power and collect thermal energy from sunlight at the same time.

### FIELD OF THE INVENTION

The present invention relate to a highly concentrating solar power generation and thermal collection apparatus, and more particularly to a highly concentrating solar power generation and thermal collection apparatus capable of generating power and collecting thermal energy from sunlight at the same time.

### BACKGROUND OF THE INVENTION

The rapid development in various industrial fields has led to the gradual depletion of petrochemical fuel and the globally concerned problem of emission of gases contribution to the greenhouse effect. As a result, the energy supply has become one of the very important global issues. Compared to the traditional large-scale power generation that uses coal, gas or nuclear energy as fuel to generate power, the solar power generation would not produce greenhouse gases and pollutant gases, such as carbon dioxide, nitric oxide, oxysulfide, etc., and is less relied on the petrochemical fuel, and is therefore more effective in the reduction of many related environment pollution. Therefore, the use of solar panels, which utilize the photoelectric effect to directly convert solar energy into electric energy, to generate energy sources has now been widely promoted as a safe and independent power source.

However, most conventional solar power generation apparatus include a plurality of solar panels set up in outdoor environment, a converter electrically connected to the solar panels, and a battery electrically connected to the converter. The solar panels receive external light energy to produce direct current, which is then converted by the converter into alternating current. The produced alternating current is then stored in the battery or is directly transmitted via a distributor to power-requiring electric apparatus for use.

The above-described solar power generation apparatus can only convert sunlight into electric energy for use while ignoring the solar thermal energy that is actually collectable for use. That is, there is still defect in the actual application of the existing solar power generation apparatus.

It is therefore tried by the inventor to develop a highly concentrating solar power generation and thermal collection apparatus that enables solar power generation and solar thermal collection at the same time.

### SUMMARY OF THE INVENTION

A primary object of the present invention is to provide a highly concentrating solar power generation and thermal collection apparatus including a multi-coated lens, so that ultraviolet (UV) light and visible light in sunlight can be reflected by the multi-coated lens to a solar cell while infrared light in sunlight is allowed to transmit through the multi-coated lens to project onto a thermal collection unit. Alternatively, the multi-coated lens can be differently designed, so that UV light and visible light in sunlight is allowed to transmit through the multi-coated lens to project onto the solar cell while infrared light in sunlight is reflected by the multi-coated lens to the thermal collection unit. With these arrangements, the apparatus is able to generate power and collect thermal energy from sunlight at the same time.

To achieve the above and other objects, a first type of the highly concentrating solar power generation and thermal collection apparatus according to the present invention utilizes UV light and visible light in the sunlight to generate power and utilizes infrared light in the sunlight to collect thermal energy at the same time. The first type of highly concentrating solar power generation and thermal collection apparatus includes a multi-coated lens that reflects the UV light and visible light and allows the infrared light to transmit therethrough; a lens located at one side of the multi-coated lens for collecting and then concentrating the sunlight on the multi-coated lens; a solar cell located on alight reflection path of the multi-coated lens for collecting the UV light and visible light reflected by the multi-coated lens; and a thermal collection unit located on a light transmission path of the multi-coated lens for collecting the infrared light transmitted through the multi-coated lens.

A second type of the highly concentrating solar power generation and thermal collection apparatus according to the present invention utilizes UV light and visible light in the sunlight to generate power and utilizes infrared light in the sunlight to collect thermal energy at the same time. The second type of highly concentrating solar power generation and thermal collection apparatus includes a multi-coated lens that reflects the infrared light and allows the UV light and visible light to transmit therethrough; a lens located at one side of the multi-coated lens for collecting and then concentrating the sunlight on the multi-coated lens; a solar cell located on a light transmission path of the multi-coated lens for collecting the UV light and visible light transmitted through the multi-coated lens; and a thermal collection unit located on a light reflection path of the multi-coated lens for collecting the infrared light reflected by the multi-coated lens.

Thus, with the multi-coated lens, the highly concentrating solar power generation and thermal collection apparatus according to the present invention is able to generate power and collect thermal energy from sunlight at the same time.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is a schematic view showing a first embodiment of a first type of highly concentrating solar power generation and thermal collection apparatus according to the present invention;

FIG. 2 is a sectional view of a curved multi-coated lens used in the present invention;

FIG. 3 is a schematic view showing a second embodiment of the first type of highly concentrating solar power generation and thermal collection apparatus according to the present invention;

FIG. 4 is a schematic view showing a third embodiment of the first type of highly concentrating solar power generation and thermal collection apparatus according to the present invention;

FIG. 5 is a schematic view showing a first embodiment of a second type of highly concentrating solar power generation and thermal collection apparatus according to the present invention;

FIG. 6 is a schematic view showing a second embodiment of the second type of highly concentrating solar power generation and thermal collection apparatus according to the present invention;

FIG. 7 is a schematic view showing a third embodiment of the second type of highly concentrating solar power generation and thermal collection apparatus according to the present invention;

FIG. 8 is a sectional view of a flat multi-coated lens used in the present invention;

FIG. 9 is a schematic view showing a fourth embodiment of the first type of highly concentrating solar power generation and thermal collection apparatus according to the present invention;

FIG. 10 is a schematic view showing a fifth embodiment of the first type of highly concentrating solar power generation and thermal collection apparatus according to the present invention;

FIG. 11 is a schematic view showing a sixth embodiment of the first type of highly concentrating solar power generation and thermal collection apparatus according to the present invention;

FIG. 12 is a schematic view showing a fourth embodiment of the second type of highly concentrating solar power generation and thermal collection apparatus according to the present invention;

FIG. 13 is a schematic view showing a fifth embodiment of the second type of highly concentrating solar power generation and thermal collection apparatus according to the present invention; and

FIG. 14 is a schematic view showing a sixth embodiment of the second type of highly concentrating solar power generation and thermal collection apparatus according to the present invention.

### DETAILED DESCRIPTION OF THE PREFERRED EMBODIMENTS

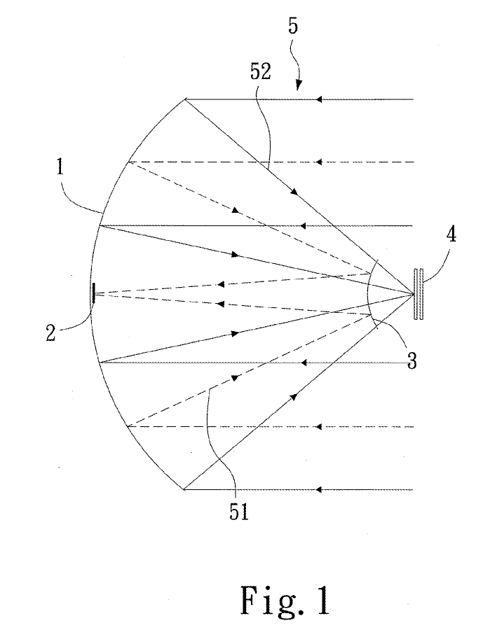

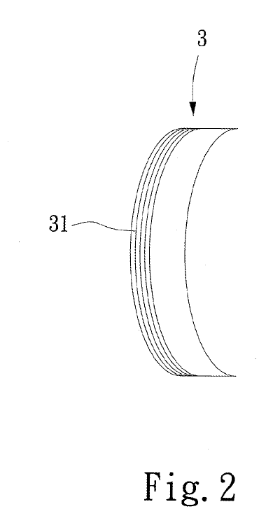

Please refer to FIG. 1 that is a schematic view of a first embodiment of a first type of highly concentrating solar power generation and thermal collection apparatus according to the present invention, and to FIG. 2 that is a sectional view of a curved multi-coated lens used in the present invention. As shown, the first type of highly concentrating solar power generation and thermal collection apparatus according to the present invention utilizes ultraviolet (UV) light and visible light 51 as well as infrared light 52 in sunlight 5 to simultaneously achieve the purposes of power generation and thermal collection. In the first type of the present invention, the highly concentrating solar power generation and thermal collection apparatus includes a lens 1, a solar cell 2, a multi-coated lens 3, and a thermal collection unit 4. The multi-coated lens 3 is able to reflect UV light and visible light 51, and allows infrared light 52 to transmit therethrough. The lens 1 is located at one side of the multi-coated lens 3. In the first embodiment illustrated in FIG. 1, the lens 1 is located at the left side of the multi-coated lens 3. The lens 1 collects sunlight 5 and concentrates the same on the multi-coated lens 3. The solar cell 2 is located on a light reflection path of the multi-coated lens 3. In the illustrated first embodiment, the solar cell 2 is located between the lens 1 and the multi-coated lens 3 without blocking the sunlight 5, and is close to the surface of the lens 1 for collecting the UV light and visible light 51 reflected by the multi-coated lens 3. The thermal collection unit 4 is located on a light transmission path of the multi-coated lens 3. In the illustrated first embodiment, the thermal collection unit 4 is located at the right side of the multi-coated lens 3 for collecting the infrared light 52 that transmits through the multi-coated lens 3. With these arrangements, the highly concentrating solar power generation and thermal collection apparatus of the present invention is able to generate electric power and collect thermal energy from sunlight at the same time. The electric power generated by the solar cell 2 can be supplied to downstream electric apparatus for use, and the thermal energy collected by the thermal collection unit 4 can be used to heat fluid or solid that is to be used by downstream apparatus.

In the first embodiment of the first type of highly concentrating solar power generation and thermal collection apparatus according to the present invention, the multi-coated lens 3 is a curved lens. The UV light and visible light 51 reflected by the multi-coated lens 3 is focused on the solar cell 2; and the infrared light 52 transmitted through the multi-coated lens 3 is focused on the thermal collection unit 4.

The aforesaid lens 1 can be a concave lens for collecting sunlight 5 and reflecting the latter to the multi-coated lens 3.

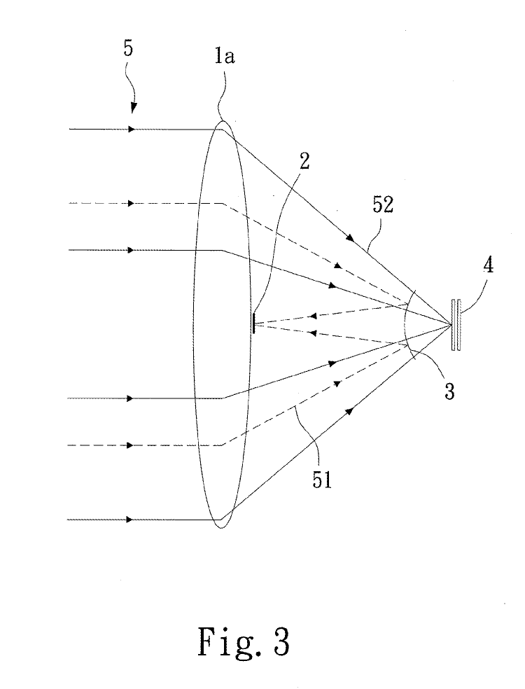

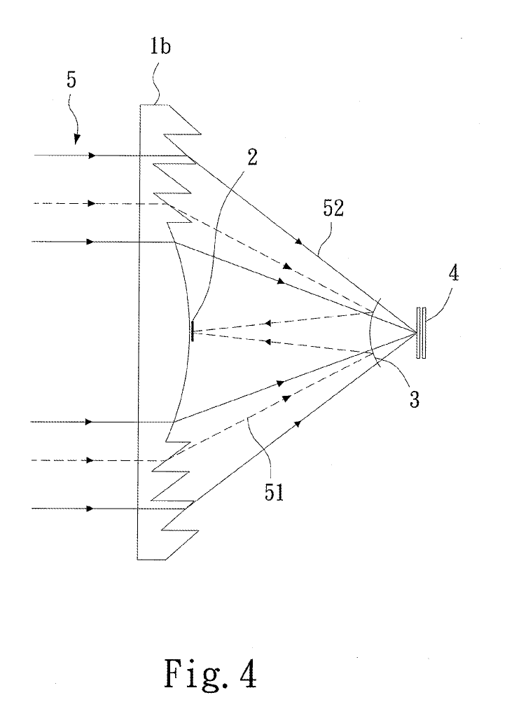

Please refer to FIGS. 3 and 4 that are second and third embodiments, respectively, of the first type of highly concentrating solar power generation and thermal collection apparatus according to the present invention. As shown, the lens 1 may also be a convex lens or a Fresnel lens for collecting sunlight 5, so that the sunlight 5 transmits through the lens 1 to reach at the multi-coated lens 3.

The aforesaid multi-coated lens 3 is formed by laminating at least three layers of different coatings 31.

The coatings 31 can be respectively formed of a material selected from the group consisting of Al₂O₃, AlF₃, Bi₂O₃, CeF₃, chromium-contained coating, HfF₄, HfO₂, MgF₂, Sc₂O₃, SiO, SiO₂, Ta₂O₅, TiO₂, Y₂O₃, ZnS and ZrO₂.

The first type of highly concentrating solar power generation and thermal collection apparatus according to the present invention in use is arranged in an outdoor environment at a position with abundant sunlight. When the sunlight 5 radiates on the lens 1, the sunlight 5 is totally reflected by the lens 1, so that the sunlight 5 as a light source is projected onto the multi-coated lens 3. At this point, the UV light and visible light 51 in the sunlight 5 is reflected by the multi-coated lens 3 to project onto the solar cell 2 to enable solar power generation. Meanwhile, the infrared light 52 in the sunlight 5 transmits through the multi-coated lens 3 to project onto the thermal collection unit 4, so that thermal energy of the sunlight 5 is collected by the thermal collection unit 4 for use later.

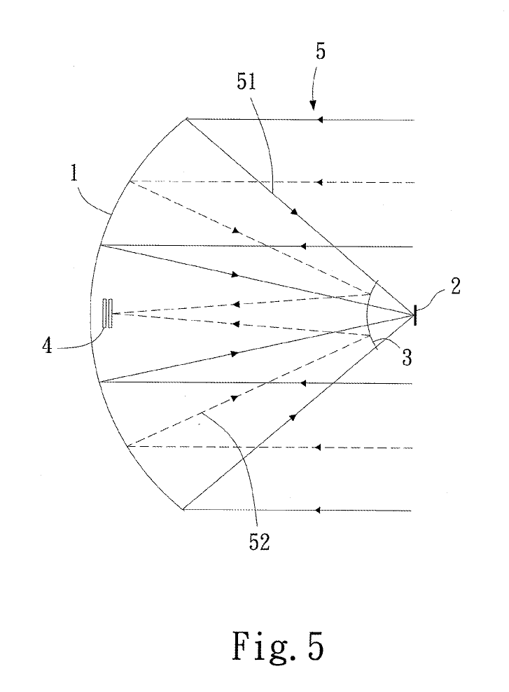

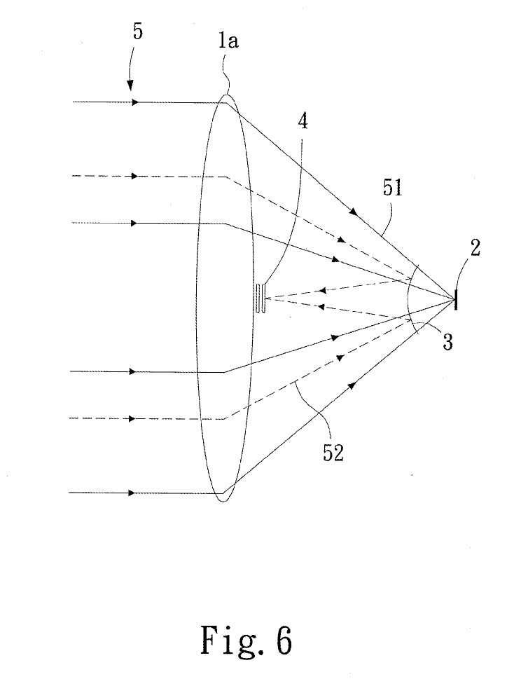

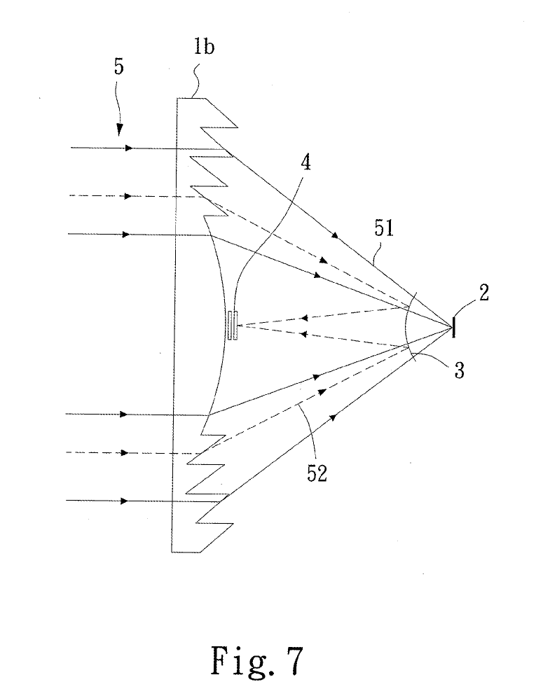

FIGS. 5, 6 and 7 respectively show first, second, and third embodiments of a second type of highly concentrating solar power generation and thermal collection apparatus according to the present invention. As shown, the second type is different from the first type in the function of the multi-coated lens 3 and the locations of the solar cell 2 and the thermal collection unit 4 relative to the multi-coated lens 3. More specifically, the multi-coated lens 3 in the second type of highly concentrating solar power generation and thermal collection apparatus is able to reflect infrared light 52 while allowing UV light and visible light 51 to transmit therethrough; and the solar cell 2 is located on the light transmission path of the multi-coated lens 3 while the thermal collection unit 4 is located on the light reflection path of the multi-coated lens 3. In the illustrated first, second and third embodiments of the second type of highly concentrating solar power generation and thermal collection apparatus according to the present invention, the solar cell 2 is located at a right side of the multi-coated lens 3 for collecting the UV light and visible light 51 transmitted through the multi-coated lens 3; and the thermal collection unit 4 is located between the lens 1 and the multi-coated lens 3 without blocking the sunlight 5, and is close to the surface of the lens 1 for collecting the infrared light 52 reflected by the multi-coated lens 3.

The second type of highly concentrating solar power generation and thermal collection apparatus according to the present invention in use is arranged in an outdoor environment at a position with abundant sunlight. When the sunlight 5 radiates on the lens 1, the sunlight 5 is totally reflected by the lens 1, so that the sunlight 5 as a light source is projected onto the multi-coated lens 3. At this point, the UV light and visible light 51 in the sunlight 5 transmits through the multi-coated lens 3 to project onto the solar cell 2 to enable solar power generation. Meanwhile, the infrared light 52 in the sunlight 5 is reflected by the multi-coated lens 3 to project onto the thermal collection unit 4, so that thermal energy of the sunlight 5 is collected by the thermal collection unit 4 for use later.

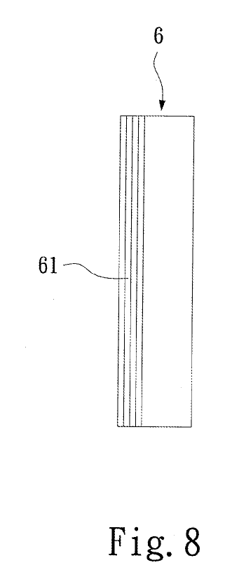

Please refer to FIG. 8 that is a sectional view of a flat multi-coated lens 6 used in the present invention. As shown, the flat multi-coated lens 6 is formed by laminating at least three layers of different coatings 61. The coatings 61 can be respectively formed of a material selected from the group consisting of Al₂O₃, AlF₂, Bi₂O₂, CeF₃, chromium-contained coating, HfF₄, HfO₂, MgF₂, Sc₂O₃, SiO, SiO₂, Ta₂O₃, TiO₂, Y₂O₃. ZnS and ZrO₂.

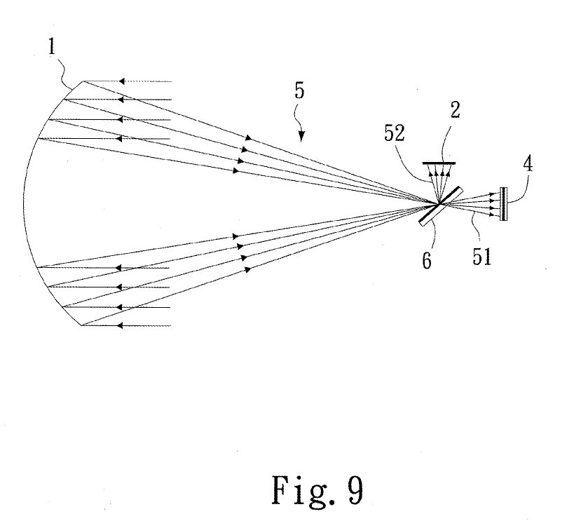

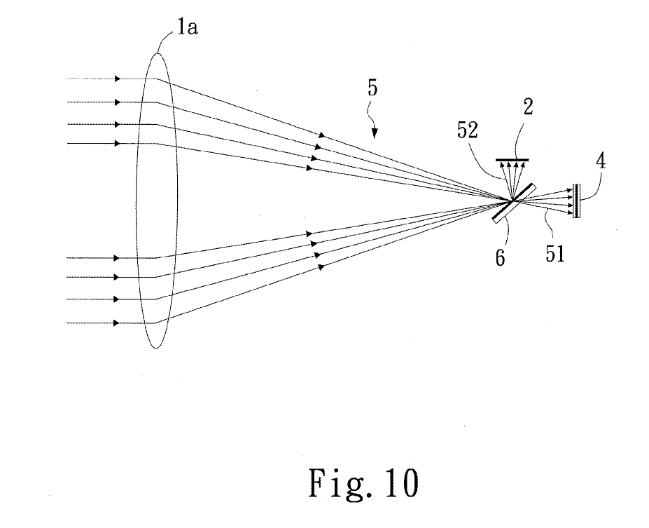

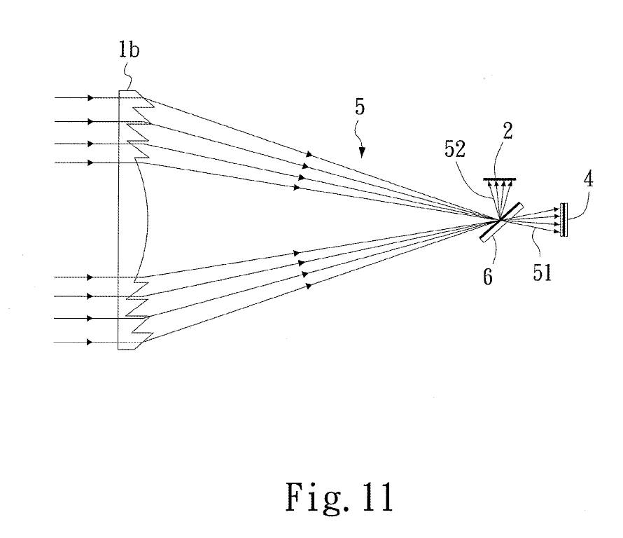

Please refer to FIGS. 9, 10 and 11 that are fourth, fifth and sixth embodiments, respectively, of the first type of highly concentrating solar power generation and thermal collection apparatus according to the present invention. As shown, in the first type of the present invention, the fourth, fifth and sixth embodiments thereof are different from the first, second and third embodiments thereof in that the multi-coated lens 6 is a flat lens and that the solar cell 2 is located above the multi-coated lens 6 without blocking the sunlight 5. Further, the multi-coated lens 6 is tilted by 45 degrees, so that the UV light and visible light 51 is reflected by the multi-coated lens 6 to project onto the solar cell 2.

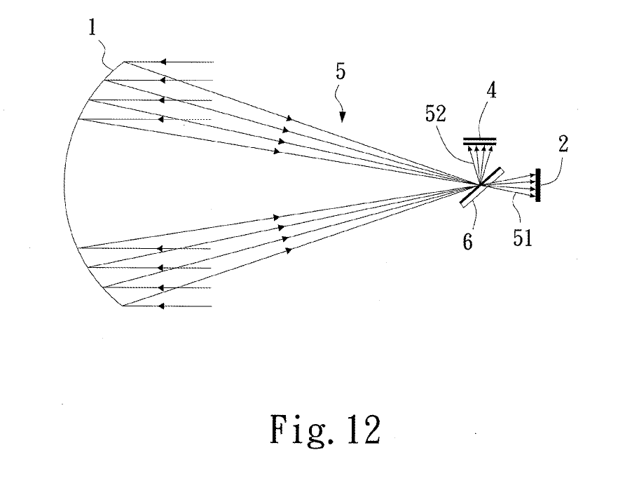

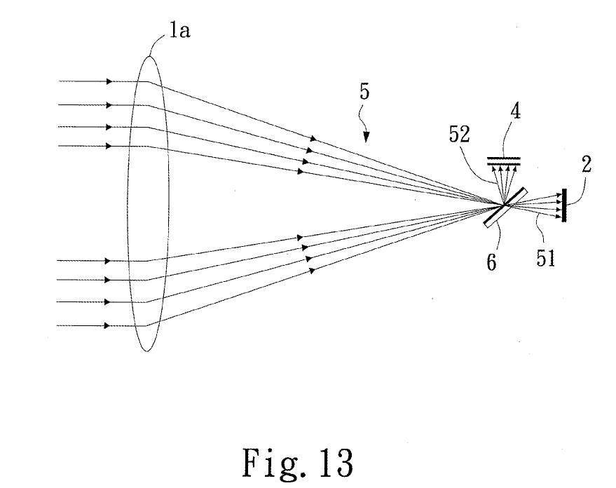

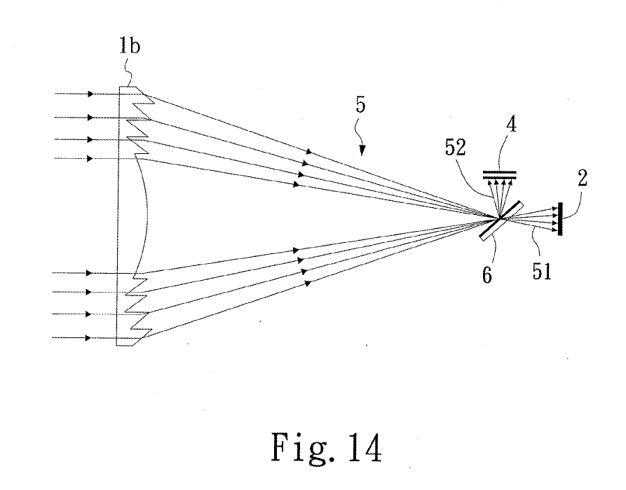

Please refer to FIGS. 12, 13 and 14 that are fourth, fifth and sixth embodiments, respectively, of the second type of highly concentrating solar power generation and thermal collection apparatus according to the present invention. As shown, in the second type of the present invention, the fourth, fifth and sixth embodiments thereof are different from the first, second and third embodiments thereof in that the multi-coated lens 6 is a flat lens and that the thermal collection unit 4 is located above the multi-coated lens 6 without blocking the sunlight 5. Further, the multi-coated lens 6 is tilted by 45 degrees, so that the infrared light 52 is reflected by the multi-coated lens 6 to project onto the thermal collection unit 4.

With the above arrangements, the present invention is novel, improved and industrially practical for use. The present invention is novel and improved because the use of the multi-coated lens simultaneously enables the reflection of UV light and visible light in the sunlight by the multi-coated lens to the solar cell for solar power generation as well as the transmission of the infrared light in the sunlight through the multi-coated to project onto the thermal collection unit for solar thermal energy collection. Therefore, the present invention enables solar power generation and solar thermal energy collection at the same time, which is industrial usable and would no doubt satisfy the current market demands.

The present invention has been described with some preferred embodiments thereof and it is understood these embodiments are only for the purpose of illustration instead of limiting the scope of the present invention, and that many changes and modifications in the described embodiments can be carried out without departing from the scope and the spirit of the invention that is intended to be limited only by the appended claims.

What is claimed is:

1. A highly concentrating solar power generation and thermal collection apparatus that utilizes UV light and visible light as well as infrared light in sunlight to simultaneously achieve the purposes of power generation and thermal collection, comprising:
a multi-coated lens being capable of reflecting UV light and visible light while allowing infrared light to transmit therethrough;
a lens being located at one side of the multi-coated lens for collecting and then concentrating sunlight on the multi-coated lens;
a solar cell being located on a light reflection path of the multi-coated lens for collecting the UV light and visible light reflected by the multi-coated lens; and
a thermal collection unit being located on a light transmission path of the multi-coated lens for collecting the infrared light transmitted through the multi-coated lens.

2. A highly concentrating solar power generation and thermal collection apparatus that utilizes UV light and visible light as well as infrared light in sunlight to simultaneously achieve the purposes of power generation and thermal collection, comprising:
a multi-coated lens being capable of reflecting infrared light while allowing UV light and visible light to transmit therethrough;
a lens being located at one side of the multi-coated lens for collecting and then concentrating sunlight on the multi-coated lens;
a solar cell being located on a light transmission path of the multi-coated lens for collecting the UV light and visible light transmitted through the multi-coated lens; and
a thermal collection unit being located on a light reflection path of the multi-coated lens for collecting the infrared light reflected by the multi-coated lens.

3. The highly concentrating solar power generation and thermal collection apparatus as claimed in claim 1, wherein the multi-coated lens is a curved multi-coated lens.

4. The highly concentrating solar power generation and thermal collection apparatus as claimed in claim 2, wherein the multi-coated lens is a curved multi-coated lens.

5. The highly concentrating solar power generation and thermal collection apparatus as claimed in claim 1, wherein the multi-coated lens is a flat multi-coated lens.

6. The highly concentrating solar power generation and thermal collection apparatus as claimed in claim 2, wherein the multi-coated lens is a flat multi-coated lens.

7. The highly concentrating solar power generation and thermal collection apparatus as claimed in claim 1, wherein when the lens is a concave lens, the lens is capable of reflecting the sunlight to the multi-coated lens; when the lens is any one of a convex lens and a Fresnel lens, the lens collects the sunlight and allows the sunlight to transmit therethrough to project onto the multi-coated lens.

8. The highly concentrating solar power generation and thermal collection apparatus as claimed in claim 2, wherein when the lens is a concave lens, the lens is capable of reflecting the sunlight to the multi-coated lens; when the lens is any one of a convex lens and a Fresnel lens, the lens collects the sunlight and allows the sunlight to transmit therethrough to project onto the multi-coated lens.

9. The highly concentrating solar power generation and thermal collection apparatus as claimed in claim 3, wherein when the lens is a concave lens, the lens is capable of reflecting the sunlight to the multi-coated lens; when the lens is any one of a convex lens and a Fresnel lens, the lens collects the sunlight and allows the sunlight to transmit therethrough to project onto the multi-coated lens.

10. The highly concentrating solar power generation and thermal collection apparatus as claimed in claim 4, wherein when the lens is a concave lens, the lens is capable of reflecting the sunlight to the multi-coated lens; when the lens is any one of a convex lens and a Fresnel lens, the lens collects the sunlight and allows the sunlight to transmit therethrough to project onto the multi-coated lens.

11. The highly concentrating solar power generation and thermal collection apparatus as claimed in claim 5, wherein when the lens is a concave lens, the lens is capable of reflecting the sunlight to the multi-coated lens; when the lens is any one of a convex lens and a Fresnel lens, the lens collects the sunlight and allows the sunlight to transmit therethrough to project onto the multi-coated lens.

12. The highly concentrating solar power generation and thermal collection apparatus as claimed in claim 6, wherein when the lens is a concave lens, the lens is capable of reflecting the sunlight to the multi-coated lens; when the lens is any one of a convex lens and a Fresnel lens, the lens collects the sunlight and allows the sunlight to transmit therethrough to project onto the multi-coated lens.

13. The highly concentrating solar power generation and thermal collection apparatus as claimed in claim 1, wherein the multi-coated lens is formed of at least three layers of different coatings.

14. The highly concentrating solar power generation and thermal collection apparatus as claimed in claim 2, wherein the multi-coated lens is formed of at least three layers of different coatings.

15. The highly concentrating solar power generation and thermal collection apparatus as claimed in claim 13, wherein the coatings are respectively formed of a material selected from the group consisting of Al₂O₃, AlF₃, Bi₂O₃, CeF₃, chromium-contained coating, HfF₄, HfO₂, MgF₂, Sc₂O₃, SiO, SiO₂, Ta₂O₅, TiO₂, Y₂O₃, ZnS and ZrO₂.

16. The highly concentrating solar power generation and thermal collection apparatus as claimed in claim 14, wherein the coatings are respectively formed of a material selected from the group consisting of Al₂O₃, AlF₃, Bi₂O₃, CeF₃, chromium-contained coating, HfF₄, HfO₂, MgF₂, Sc₂O₃, SiO, SiO₂, Ta₂O₅, TiO₂, Y₂O₃, ZnS and ZrO₂.
